(19) United States
(12) Patent Application Publication
(10) Pub. No.: US 2008/0265394 A1
(43) Pub. Date: Oct. 30, 2008

(54) WAFER LEVEL PACKAGE AND FABRICATING METHOD THEREOF

(75) Inventor: Changhan Kim, Seoul (KR)

Correspondence Address: HUSCH BLACKWELL SANDERS LLP, 720 OLIVE STREET, SUITE 2400, ST. LOUIS, MO, 63101, US

(73) Assignee: MTEKVISION CO., LTD., Seoul (KR)

(21) Appl. No.: 11/742,169

(22) Filed: Apr. 30, 2007

(51) Int. Cl. H01L 21/50; H01L 23/482

(52) U.S. Cl. 257/690; 257/701; 438/125; 257/E23.016; 257/E21.499

(57) ABSTRACT

A wafer level semiconductor package and fabricating method thereof are disclosed. A method of fabricating a wafer level package, which includes depositing a first insulation layer on the outermost layer circuit of the a semiconductor chip and then flattening the surface of the first insulation layer; removing a portion of the first insulation layer to expose a chip pad to the outside; depositing a metal layer directly contacting the chip pad onto the chip pad and the first insulation layer and then removing a portion to form a bump metal having a bump pad electrically connected with the chip pad; and depositing a second insulation layer and a coating layer in order onto the bump metal and then removing portions thereof to expose the bump pad to the outside, where all of the operations are performed by semiconductor fabrication (FAB) equipment, not only enables the forming of higher-precision patterns, but also reduces volume.

### BACKGROUND

1. Technical Field

This invention relates to chip scale packages and methods for manufacturing the chip scale packages at wafer level.

2. Description of the Related Art

The current trend in the electronics industry is towards fabricating lighter and smaller products having more functionality, greater capabilities, and high reliability. One important technology that makes it possible to reach such goals in product design is package assembly technology. A semiconductor chip, on which an integrated circuit has been formed by a wafer assembly process, is given the form of a package by means of package assembly technology, which may provide the advantages of protecting the semiconductor chip from the external environment, allowing easier mounting, and ensuring the reliability of its actions.

While various package forms according to various package assembly technologies have been introduced to date, the chip scale package is receiving particular attention. Chip Scale Package, or CSP is a single-die, direct surface mountable package with an area of no more than 1.2× the original die area. Such a chip scale package has many advantages over the conventional plastic package, especially in that the size is so small. Chip scale packages are mainly used, due to these advantages, in products requiring small size and mobility, such as digital camcorders, portable phones, laptop computers, and memory cards, etc., and semiconductor elements such as DSP's (digital signal processors), ASIC's (application-specific integrated circuits), and microcontrollers, etc., are mounted in chip scale packages. In addition, the use of chip scale packages is also gradually increasing in which memory elements such as DRAM (dynamic random access memory) and flash memory, etc., are mounted.

However, although the chip scale package has unequalled superiority in terms of its size, there may still be several drawbacks compared to the conventional plastic package. One may be difficulty in ensuring reliability, and another may be lowered price competitiveness, due to the large quantities of additional fabrication facilities invested and raw materials consumed in fabricating chip scale packages, and the high unit costs.

As a means to resolve such problems, the wafer level chip scale package (hereinafter referred to as “wafer level package”) is being proposed. The wafer level package refers to the technology of packaging an integrated circuit at wafer level, instead of the traditional process of assembling the package of each individual unit after wafer dicing. The wafer level package is a form of package that does not undergo assembly with separated semiconductor chips, but rather is fabricated by the operations of rewiring, forming ball-shaped external connection terminals, and separating into individual semiconductor chips, on a semiconductor wafer fabricated by a wafer assembly process. The wafer level package provides benefits in the thermal and electrical properties and small size of the package, as well as providing the benefits of reduced cost and increased effect of applying the wafer level test. Furthermore, conventional wafer assembly facilities and processes may be utilized in the fabrication facilities and fabrication processes used for fabricating the package, and the additional raw materials required for fabricating the package may be minimized.

With the conventional wafer level package, coating and insulation are performed on a semiconductor chip, on which semiconductor fabrication (hereinafter referred to as “FAB”) has been completed, using a polymide-base material. The wafer level packaging process applied here used metal wet etching equipment and patterning equipment, etc. However, since the metal wet etching equipment and patterning equipment are limited to patterning of the micrometer (μm) level, it is impossible to form patterns of higher precision. Also, as the mass production processes currently applied are limited to using two BCB (benzocyclobutene) layers and two redistribution layers for interconnection, there is difficulty in implementing large-number pin-outs.

### SUMMARY

An aspect of the invention is to provide a wafer level package and fabricating method thereof that enable the forming of higher-precision patterns using semiconductor fabrication (FAB) equipment.

Another aspect of the invention is to provide a wafer level package and fabricating method thereof with which the volume can be decreased, by forming interconnection pads to obviate the need to form redistribution layers.

One aspect of the invention provides a method of fabricating a wafer level package, which includes depositing a first insulation layer on the outermost layer circuit of the a semiconductor chip and then flattening the surface of the first insulation layer; removing a portion of the first insulation layer to expose a chip pad to the outside; depositing a metal layer directly contacting the chip pad onto the chip pad and the first insulation layer and then removing a portion to form a bump metal having a bump pad electrically connected with the chip pad; and depositing a second insulation layer and a coating layer in order onto the bump metal and then removing portions thereof to expose the bump pad to the outside, where all of the operations are performed by semiconductor fabrication (FAB) equipment.

The method of fabricating a wafer level package according to an aspect of the invention may include one or more of the following features. For example, the metal layer may be an under-bump metal, and an under-bump metal may additionally be stacked on the bump pad. The coating layer may be made of a nitride, and the first insulation layer and the second insulation layer may be oxide layers. Also, the flattening of the first insulation layer may be performed by chemical mechanical polishing or by an etch back process of spin-on glass.

The bump metals on both end portions of the outermost layer circuit may each form an electrically connected interconnection pad. Also, a solder ball may be formed on the bump pad, and the size of the bump pad exposed to the outside may be 50 to 85% of the diameter of the solder ball.

Another aspect of the invention provides a wafer level package that includes a semiconductor chip on which an outermost layer circuit and a chip pad are formed, a first insulation layer which is stacked on the semiconductor chip and which has a concave that exposes the chip pad to the outside, a bump metal stacked onto the chip pad and the first insulation layer with one end electrically connected to the chip pad and the other end having a bump pad formed thereon, and a second insulation layer and a coating layer stacked in order on the bump metal, where the second insulation layer and the coating layer have concaves that expose the bump pad to the outside.

The bump metal may be made of an under-bump metal, and the wafer level package may include an under-bump metal stacked on the bump pad. Also, the coating layer may be made of a nitride, and the first insulation layer and the second insulation layer may be oxide layers. The wafer level package may include an interconnection pad made of a pair of bump metals each electrically connected to either end of the outermost layer circuit, with one of the bump metals connected to the chip pad and the other connected to the bump pad.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a plan view illustrating an arrangement of bump pads and signal lines and power lines connected thereto.

FIG. 2 is a cross sectional view illustrating a first insulation layer stacked on a semiconductor chip in a method of fabricating a wafer level package according to an embodiment of the invention.

FIG. 3 is a cross sectional view illustrating the first insulation layer of FIG. 2 with one side flattened.

FIG. 4 is a cross sectional view illustrating the first insulation layer of FIG. 3 with a portion removed to expose the chip pad.

FIG. 5 is a cross sectional view illustrating the configuration of FIG. 4 after depositing a bump metal.

FIG. 6 is a cross sectional view illustrating the configuration of FIG. 5 after depositing an oxide and nitride and then removing portions thereof to expose the bump pad.

FIG. 7 is a cross sectional view of interconnection pads according to an embodiment of the invention.

### DETAILED DESCRIPTION

The wafer level package and fabricating method thereof according to certain embodiments of the invention will be described below in more detail with reference to the accompanying drawings, in which those components are rendered the same reference number that are the same or are in correspondence, regardless of the figure number, and redundant explanations are omitted. Also, the dotted lines illustrated in FIGS. 2 to 6 mean that other layers including circuit layers may be formed between the semiconductor chip 21 and the outermost layer circuit 19.

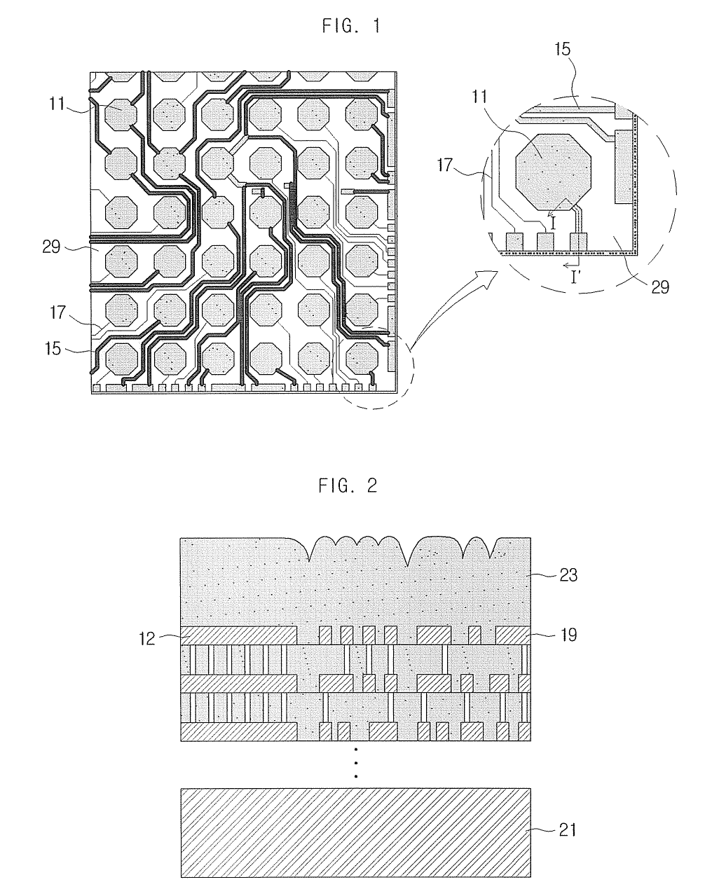

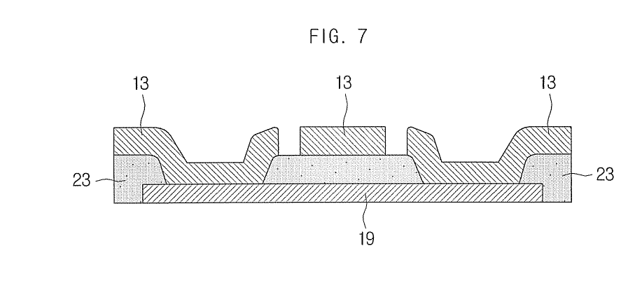

In FIG. 1 is illustrated an edge pad type semiconductor chip 21, on which a plurality of chip pads are formed along the edges. A plurality of bump pads 11 are formed on the semiconductor chip 21, where such bump pads 11 are electrically connected with the chip pads 12 by power lines 15 or signal lines 17. While it is not illustrated in FIG. 1, solder balls (not shown) are attached onto the bump pads 11. All of the bump pads 11 are connected with the chip pads 12 by power lines 15 or signal lines 17. Also, if there is no space for connecting a chip pad 12 and a bump pad 11, the two are connected by forming interconnection pads, as illustrated in FIG. 7. The interconnection pads will be further described later.

The power lines 15 are lines for supplying power to the semiconductor chip 21, and the signal lines 17 are lines through which control signals, etc., are inputted to the semiconductor chip 21. In general, the power lines 15 are wider than the signal lines 17.

A cross sectional view across line I-I′ of FIG. 1 is illustrated in FIG. 6. Referring to FIG. 6, a bump metal 13 is formed on a chip pad 12 of the semiconductor chip 21. One end of this bump metal 13 is in direct electrical contact with the chip pad 12, while the other end is formed by an etching process, etc., into a bump pad 11 (see FIG. 1). In addition, a coating layer 29 and a second insulation layer 27 are stacked on the bump metal 13, after which portions thereof are removed to expose the bump pad 11 to the outside.

A description will be given below on a method of fabricating a wafer level package according to an embodiment of the invention, with reference to FIGS. 2 to 6. The method of fabricating a wafer level package described below is performed by semiconductor fabrication (FAB) equipment, which currently allows precision processing of up to several tens of nanometers (nm).

Referring to FIG. 2, circuit layers made of a plurality of layers are formed on the semiconductor chip 21, among which the outermost layer circuit 19 refers to the layer formed on the outermost layer on one or both sides of the semiconductor chip 21. A first insulation layer 23 is stacked on the upper portion of the outermost layer circuit 19, where the first insulation layer 23 may be an oxide layer. The first insulation layer 23 may be given a thickness of a minimum 5 μm or less by a subsequent flattening process, and considering the resistance and current driving capability of the first insulation layer 23, may be formed to a thickness of 10 μm. Increasing the thickness of the first insulation layer 23 reduces the resistance while improving the current driving capability.

Since the method of fabricating a wafer level package according to this embodiment is performed by semiconductor fabrication (FAB) equipment, an oxide layer may be formed from the first insulation layer 23.

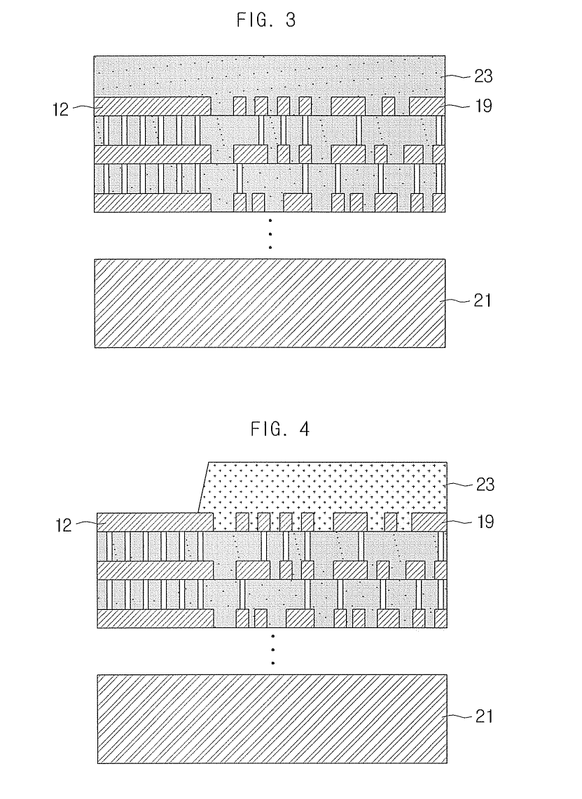

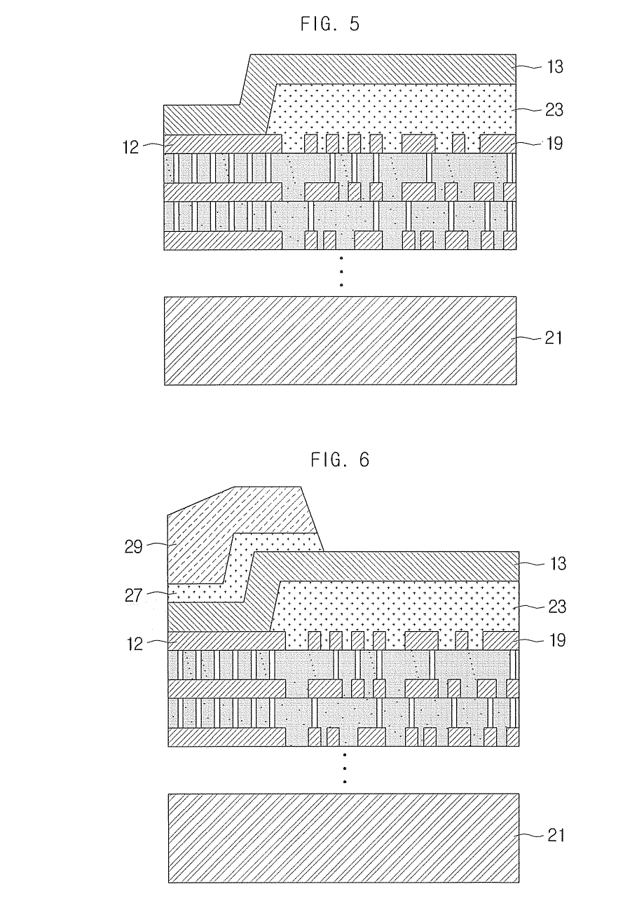

Referring to FIG. 3, one side of the first insulation layer 23 is processed into a substantially flat surface by a flattening process. The flattening process may be selected, according to the thickness of the bump metal (13 of FIG. 5) to be formed subsequently and the pitch sizes of the power lines 15 or signal lines 17, from chemical mechanical polishing or an etch back process of spin-on glass. By such flattening processes, the thickness of the first insulation layer 23 may be formed to a minimum of 5 μm or more or 10 μm or more.

Referring to FIG. 4, a portion of the first insulation layer 23 is removed such that a portion of the chip pad 12 is exposed to the outside. A method of removing the first insulation layer 23 is to apply exposure using a photo mask, and then to remove the portion of the first insulation layer 23 by a wet etching process, etc. The chip pad 12 is connected directly with the bump metal 13 by a subsequent process.

Referring to FIG. 5, a bump metal 13 is formed on the upper portions of the chip pad 12 and the first insulation layer 23. The bump metal 13 is formed by processing a metal layer, stacked on the chip pad 12 and the first insulation layer 23, by an etching process, etc., and is composed of the portion directly contacting the chip pad 12, the bump pad 11, and the power line 15 or signal line 17.

The bump pad 11, as illustrated in FIG. 1, has an octagonal shape, and by a subsequent process, has a solder ball attached to one side. The size of the bump pad 11 exposed to the outside may be processed to about 50 to 85% of the diameter of the solder ball. As such, the bump pad 11, while electrically connected with the chip pad 12, provides a space in which a solder ball may be attached, and serves to secure the space where the solder ball may be attached by drawing the chip pad 12 out towards the center of the semiconductor chip 21.

The bump metal 13 may be made of an under-bump metal. An under-bump metal has superb adhesion to the solder ball made of tin (Sn), etc. In addition, the bump metal 13 may be made of common aluminum (Al) or copper (Cu), etc. When the bump metal 13 is thus made of a metal other than an under-bump metal, the under-bump metal may additionally be stacked on the bump metal 13 by a subsequent process.

As illustrated in FIG. 6, a second insulation layer 27 and a coating layer 29 are stacked on the bump metal 13 and then portions are removed to expose a portion of the bump pad 11 to the outside. A method of removing the second insulation layer 27 and coating layer 29 may include etching using a photo mask. The second insulation layer 27 may include an oxide, and the coating layer 29 may be a nitride. Not only are nitrides especially resistant to moisture, but they are also low in conductivity, to provide the advantage of superb insulation properties.

Also, when the bump metal 13 is not formed by an under-bump metal, the adhesion of the solder ball may be increased by depositing an under-bump metal on the coating layer 29 and the bump pad 11 and then etching using a pattern.

As such, since the wafer level package and fabricating method thereof according to this embodiment uses semiconductor fabrication (FAB) equipment, the power lines 15 and signal lines 17 may be precision processed up to several tens of nanometers (nm). Also, since semiconductor fabrication (FAB) equipment is used, it is possible not only to utilize chemical mechanical polishing, but also to stack oxide layers and nitrides.

Referring to FIG. 7, an embodiment of the interconnection pads of the wafer level package is composed of a pair of separated bump metals 13 each electrically connected to either end of the outermost layer circuit 19. When the chip pad and bump pad cannot be connected by another bump metal 13, the bump metal 13 connected with the chip pad and the bump metal 13 connected with the bump pad 11 are electrically connected by the outermost layer circuit 19. As such, with the wafer level package based on this embodiment, interconnection pads are used, so that it is not necessary to form separate connection layers or via concaves, whereby the volume of the package may be reduced.

According to certain aspects of the invention as set forth above, a wafer level package and fabricating method thereof are provided that enable the forming of higher-precision patterns using semiconductor fabrication (FAB) equipment.

Also, a wafer level package and fabricating method thereof are provided, with which the volume can be decreased.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A process for manufacturing a semiconductor package at a wafer level, the method comprising the steps of:
depositing a first insulation layer on an outermost layer circuit and a chip pad;
flattening the surface of the first insulation layer;
etching a portion of the first insulation layer to partially expose the chip pad to the outside;
depositing a metal layer onto the exposed chip pad and the first insulation layer to form a bump metal wherein the bump metal includes a bump pad and a chip pad contact portion which is electrically connected to the chip pad;
depositing a second insulation layer and a coating layer in order onto the bump metal;
etching at least one portion of the second insulation layer and the coating layer to expose the bump pad to the outside,
wherein the steps are performed by semiconductor fabrication (FAB) equipment.

2. The method of claim 1, wherein the metal layer is an under-bump metal.

3. The method of claim 1, wherein an under-bump metal is additionally deposited on the bump pad.

4. The method of claim 1, wherein the coating layer is made of a nitride.

5. The method of claim 1, wherein the flattening of the first insulation layer is performed by chemical mechanical polishing.

6. The method of claim 1, wherein the flattening of the first insulation layer is performed by an etch back process of spin-on glass.

7. The method of claim 1, wherein the first insulation layer and the second insulation layer are oxide layers.

8. The method of claim 1, wherein the bump metals on both end portions of the outermost layer circuit each form an electrically connected interconnection pad.

9. The method of claim 1, wherein a solder ball is formed on the bump pad after the completion of exposing the bump pad.

10. The method of claim 9, wherein the size of the bump pad exposed to the outside is 50 to 85% of the diameter of the solder ball.

11. A wafer level package comprising:
a semiconductor chip having an outermost layer circuit and a chip pad formed thereon;
a first insulation layer stacked on the semiconductor chip and having a concave configured to expose the chip pad to the outside;
a bump metal stacked onto the chip pad and the first insulation layer with one end thereof electrically connected to the chip pad and the other end thereof having a bump pad formed thereon; and
a second insulation layer and a coating layer stacked in order on the bump metal,
wherein the second insulation layer and the coating layer have concaves configured to expose the bump pad to the outside.

12. The wafer level package of claim 11, wherein the bump metal is made of an under-bump metal.

13. The wafer level package of claim 11, wherein the wafer level package comprises an under-bump metal stacked on the bump pad.

14. The wafer level package of claim 11, wherein the coating layer is made of a nitride.

15. The wafer level package of claim 11, wherein the first insulation layer and the second insulation layer are oxide layers.

16. The wafer level package of claim 11, wherein the wafer level package comprises an interconnection pad made of a pair of bump metals each electrically connected to either end of the outermost layer circuit, and
one of the bump metals is connected to the chip pad and the other is connected to the bump pad.
